(19) United States
(12) Patent Application Publication
(10) Pub. No.: US 2025/0157868 A1
(43) Pub. Date: May 15, 2025

(54) SEMICONDUCTOR STRUCTURE

(71) Applicant: United Microelectronics Corp., Hsinchu (TW)

(72) Inventors: Chen-Hsiao Wang, Hsinchu City (TW); Kai-Kuang Ho, Hsinchu City (TW)

(73) Assignee: United Microelectronics Corp., Hsinchu (TW)

(21) Appl. No.: 18/533,191

(22) Filed: Dec. 8, 2023

(30) Foreign Application Priority Data
Nov. 9, 2023 (TW) 112143293

(51) Int. Cl. H01L 23/18; H01L 23/29; H01L 23/31

(52) U.S. Cl. CPC H01L 23/18; H01L 23/293; H01L 23/3171; H01L 23/3192

(57) ABSTRACT

A semiconductor structure including a substrate, a pad, a passivation layer, a stress buffer layer, and a bump is provided. The pad is located on the substrate. The passivation layer is located on the substrate. The passivation layer covers a portion of the pad. The stress buffer layer covers the passivation layer. The bump is located on the pad and the stress buffer layer. There is a first recess at an edge of the pad. A bottom surface of the first recess is lower than a top surface of the pad. The stress buffer layer fills the first recess.

### CROSS-REFERENCE TO RELATED APPLICATION

This application claims the priority benefit of Taiwan application serial no. 112143293, filed on Nov. 9, 2023. The entirety of the above-mentioned patent application is hereby incorporated by reference herein and made a part of this specification.

### BACKGROUND

### Technical Field

The invention relates to a semiconductor structure, and particularly relates to a semiconductor structure that can prevent the passivation layer from cracking.

### Description of Related Art

In a semiconductor structure, a passivation layer is disposed on a pad. However, after a bump is formed on the pad, the stress caused by the bump will cause damage to the passivation layer, thereby causing cracks in the passivation layer.

### SUMMARY

The invention provides a semiconductor structure, which can prevent the passivation layer from cracking.

The invention provides a semiconductor structure, which includes a substrate, a pad, a passivation layer, a stress buffer layer, and a bump. The pad is located on the substrate. The passivation layer is located on the substrate. The passivation layer covers a portion of the pad. The stress buffer layer covers the passivation layer. The bump is located on the pad and the stress buffer layer. There is a first recess at the edge of the pad. The bottom surface of the first recess is lower than the top surface of the pad. The stress buffer layer fills the first recess.

According to an embodiment of the invention, in the semiconductor structure, the pad may include a center portion and an edge portion. The edge portion may surround the center portion.

According to an embodiment of the invention, in the semiconductor structure, the thickness of the edge portion may be smaller than the thickness of the center portion.

According to an embodiment of the invention, in the semiconductor structure, the passivation layer may cover the edge portion.

According to an embodiment of the invention, in the semiconductor structure, the first recess may be located directly above the edge portion.

According to an embodiment of the invention, in the semiconductor structure, the first recess may be located between the sidewall of the center portion and the sidewall of the passivation layer.

According to an embodiment of the invention, the semiconductor structure may further include a dielectric layer. The dielectric layer is located between the pad and the substrate.

According to an embodiment of the invention, in the semiconductor structure, the dielectric layer may have a second recess. The second recess is located directly below the first recess.

According to an embodiment of the invention, in the semiconductor structure, the pad may fill the second recess.

According to an embodiment of the invention, in the semiconductor structure, a portion of the stress buffer layer filling the first recess may form a stress buffer ring.

According to an embodiment of the invention, in the semiconductor structure, the top-view pattern of the stress buffer ring may be located within the contour of the top-view pattern of the pad.

According to an embodiment of the invention, in the semiconductor structure, the top-view pattern of the first recess may be a ring shape.

According to an embodiment of the invention, in the semiconductor structure, the top-view pattern of the pad may be a polygon or a circle.

According to an embodiment of the invention, in the semiconductor structure, the passivation layer may be a single-layer structure.

According to an embodiment of the invention, in the semiconductor structure, the passivation layer may be a multilayer structure.

According to an embodiment of the invention, in the semiconductor structure, the material of the stress buffer layer is, for example, a polymer material.

According to an embodiment of the invention, in the semiconductor structure, the polymer material is, for example, polyimide.

According to an embodiment of the invention, in the semiconductor structure, the bump may be electrically connected to the pad.

According to an embodiment of the invention, in the semiconductor structure, the bump may be a single-layer structure.

According to an embodiment of the invention, in the semiconductor structure, the bump may be a multilayer structure.

Based on the above description, in the semiconductor structure according to the invention, the passivation layer covers a portion of the pad. The stress buffer layer covers the passivation layer. The bump is located on the pad and the stress buffer layer. There is a first recess at the edge of the pad. The bottom surface of the first recess is lower than the top surface of the pad. The stress buffer layer fills the first recess. Therefore, the thickness of the stress buffer layer adjacent to the edge of the pad can be increased, thereby reducing the stress applied on the passivation layer. In this way, the passivation layer can be prevented from cracking.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a semiconductor structure according to some embodiments of the invention.

FIG. 2 is a schematic top view of a pad and a stress buffer ring in FIG. 1.

FIG. 3 is a schematic top view of a pad and a stress buffer ring according to other embodiments of the invention.

FIG. 4 is a cross-sectional view of a semiconductor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

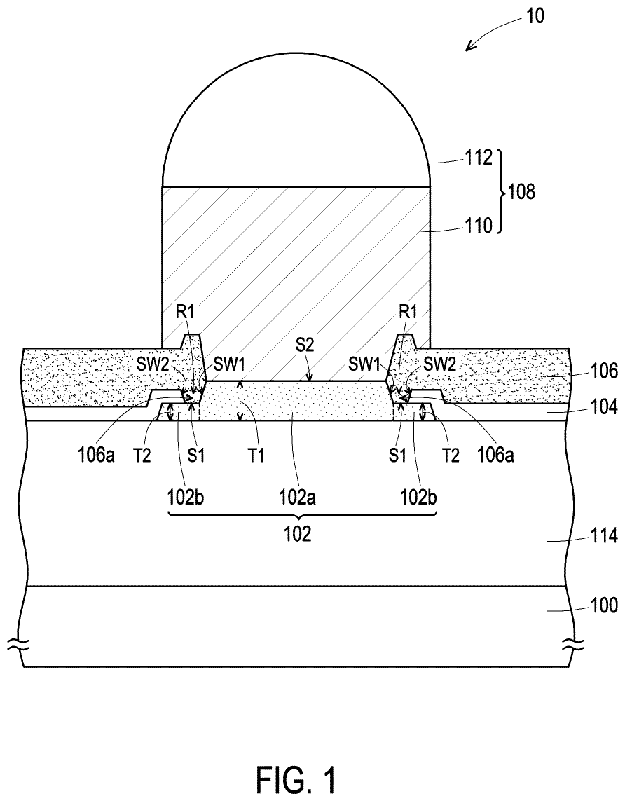

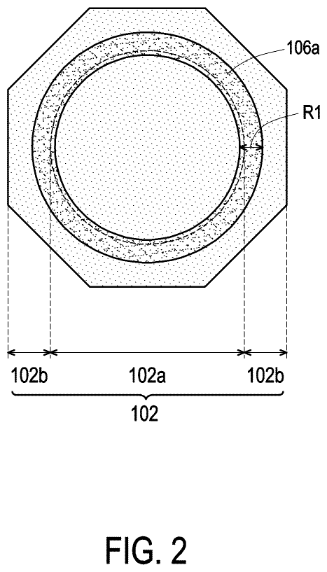

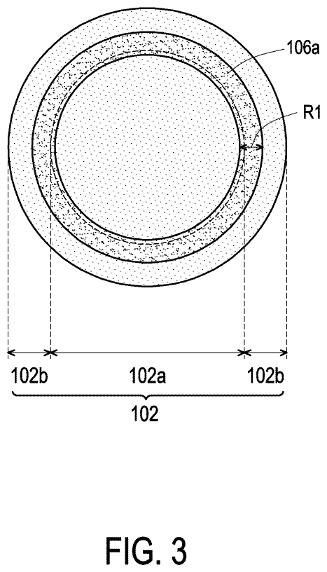

FIG. 1 is a cross-sectional view of a semiconductor structure according to some embodiments of the invention. FIG. 2 is a schematic top view of a pad and a stress buffer ring in FIG. 1. FIG. 3 is a schematic top view of a pad and a stress buffer ring according to other embodiments of the invention.

Referring to FIG. 1, a semiconductor structure 10 includes a substrate 100, a pad 102, a passivation layer 104, a stress buffer layer 106, and a bump 108. In some embodiments, the substrate 100 may be a semiconductor substrate such as a silicon substrate.

The pad 102 is located on the substrate 100. The pad 102 may include a center portion 102a and an edge portion 102b. The thickness T2 of the edge portion 102b may be smaller than the thickness T1 of the center portion 102a. As shown in FIG. 2 and FIG. 3, the edge portion 102b may surround the center portion 102a. In some embodiments, as shown in FIG. 2, the top-view pattern of the pad 102 may be a polygon, such as an octagon, but the invention is not limited thereto. In other embodiments, as shown in FIG. 3, the top-view pattern of the pad 102 may be a circle. In some embodiments, the material of the pad 102 is, for example, a conductive material such as aluminum.

The passivation layer 104 is located on the substrate 100. The passivation layer 104 covers a portion of the pad 102. The passivation layer 104 may cover the edge portion 102b. In the present embodiment, the thickness T2 of the edge portion 102b is smaller than the thickness T1 of the center portion 102a, and the passivation layer 104 covers the edge portion 102b, so there is a recess R1 at the edge of the pad 102. The bottom surface S1 of the recess R1 is lower than the top surface S2 of the pad 102. The recess R1 may be located directly above the edge portion 102b. The recess R1 may be located between the sidewall SW1 of the center portion 102a and the sidewall SW2 of the passivation layer 104. As shown in FIG. 2 and FIG. 3, the top-view pattern of the recess R1 may be a ring shape. The passivation layer 104 may be a single-layer structure or a multilayer structure. In some embodiments, the passivation layer 104 may be a silicon oxide layer, a silicon nitride layer, or a combination thereof.

The stress buffer layer 106 covers the passivation layer 104. The stress buffer layer 106 may further cover a portion of the pad 102. The stress buffer layer 106 fills in the recess R1. The portion of the stress buffer layer 106 filling the recess R1 may form a stress buffer ring 106a. As shown in FIG. 2 and FIG. 3, the top-view pattern of the stress buffer ring 106a may be located within the contour of the top-view pattern of the pad 102. In some embodiments, the material of the stress buffer layer 106 is, for example, a polymer material. In some embodiments, the polymer material is, for example, polyimide.

The bump 108 is located on the pad 102 and the stress buffer layer 106. The bump 108 may be electrically connected to the pad 102. In some embodiments, the bump 108 may include a conductive pillar, a solder ball, or a combination thereof. The bump 108 may be a single-layer structure or a multilayer structure. In the present embodiment, the bump 108 is, for example, a multilayer structure, but the invention is not limited thereto. For example, the bump 108 may include a conductive pillar 110 and a solder ball 112. The conductive pillar 110 is located on the pad 102 and the stress buffer layer 106. In some embodiments, the conductive pillar 110 is, for example, a copper pillar. The solder ball 112 is located on the conductive pillar 110. In some embodiments, the material of the solder ball 112 is, for example, Sn—Ag alloy (SnAg).

The semiconductor structure 10 may further include a dielectric layer 114. The dielectric layer 114 is located between the pad 102 and the substrate 100. The dielectric layer 114 may be further located between the passivation layer 104 and the substrate 100. The dielectric layer 114 may be a single-layer structure or a multilayer structure. In some embodiments, the material of the dielectric layer 114 is, for example, silicon oxide. In addition, although not shown in the figure, the dielectric layer 114 may have required components therein, such as semiconductor devices and/or interconnect structures, and the description thereof is omitted here.

Furthermore, although not shown in the figure, the substrate 100 may have required components thereon, such as semiconductor devices (e.g., active devices and/or passive devices), other dielectric layers and/or interconnect structures, and the description thereof is omitted here.

Based on the above embodiments, in the semiconductor structure 10, the passivation layer 104 covers a portion of the pad 102. The stress buffer layer 106 covers the passivation layer 104. The bump 108 is located on the pad 102 and the stress buffer layer 106. There is a recess R1 at the edge of the pad 102. The bottom surface S1 of the recess R1 is lower than the top surface S2 of the pad 102. The stress buffer layer 106 fills in the recess R1. Therefore, the thickness of the stress buffer layer 106 adjacent to the edge of the pad 102 can be increased, thereby reducing the stress applied on the passivation layer 104. In this way, the passivation layer 104 can be prevented from cracking.

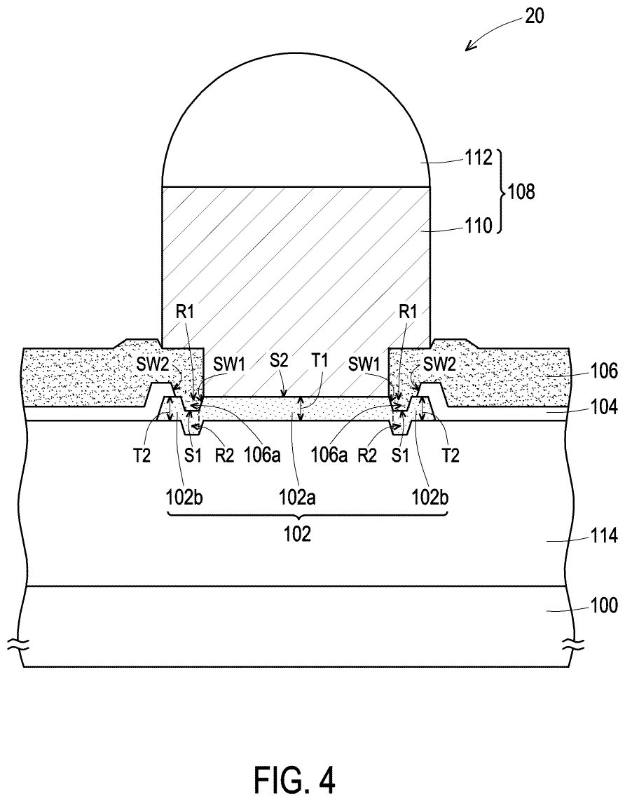

FIG. 4 is a cross-sectional view of a semiconductor structure according to other embodiments of the invention.

Referring to FIG. 1 and FIG. 4, the difference between the semiconductor structure 20 of FIG. 4 and the semiconductor structure 10 of FIG. 1 is as follows. In the semiconductor structure 20 of FIG. 4, the dielectric layer 114 may have a recess R2. The pad 102 may fill the recess R2. In the embodiment of FIG. 4, the pad 102 fills the recess R2, so the pad 102 has a recess R1 at the location corresponding to the recess R2. Therefore, there is a recess R1 at the edge of the pad 102. The recess R2 is located directly below the recess R1.

In some embodiments, in the semiconductor structure 20 of FIG. 4, the thickness T1 of the center portion 102a may be the same as or similar to the thickness T2 of the edge portion 102b. In addition, in the semiconductor structure 10 of FIG. 1 and the semiconductor structure 20 of FIG. 4, the same or similar components are denoted by the same reference symbols, and the description thereof is omitted.

Based on the above embodiment, in the semiconductor structure 20, the passivation layer 104 covers a portion of the pad 102. The stress buffer layer 106 covers the passivation layer 104. The bump 108 is located on the pad 102 and the stress buffer layer 106. There is a recess R1 at the edge of the pad 102. The bottom surface S1 of the recess R1 is lower than the top surface S2 of the pad 102. The stress buffer layer 106 fills in the recess R1. Therefore, the thickness of the stress buffer layer 106 adjacent to the edge of the pad 102 can be increased, thereby reducing the stress applied on the passivation layer 104. In this way, the passivation layer 104 can be prevented from cracking.

In summary, in the semiconductor structure of the aforementioned embodiments, the passivation layer covers a portion of the pad. The stress buffer layer covers the passivation layer. The bump is located on the pad and the stress buffer layer. There is a recess at the edge of the pad. The bottom surface of the recess is lower than the top surface of the pad. The stress buffer layer fills the recess. Therefore, the thickness of the stress buffer layer adjacent to the edge of the pad can be increased, thereby reducing the stress applied on the passivation layer. In this way, the passivation layer can be prevented from cracking.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate;
a pad located on the substrate;
a passivation layer located on the substrate and covering a portion of the pad;
a stress buffer layer covering the passivation layer; and
a bump located on the pad and the stress buffer layer, wherein
there is a first recess at an edge of the pad,
a bottom surface of the first recess is lower than a top surface of the pad, and
the stress buffer layer fills the first recess.

2. The semiconductor structure according to claim 1, wherein the pad comprises a center portion and an edge portion, and the edge portion surrounds the center portion.

3. The semiconductor structure according to claim 2, wherein a thickness of the edge portion is smaller than a thickness of the center portion.

4. The semiconductor structure according to claim 2, wherein the passivation layer covers the edge portion.

5. The semiconductor structure according to claim 2, wherein the first recess is located directly above the edge portion.

6. The semiconductor structure according to claim 2, wherein the first recess is located between a sidewall of the center portion and a sidewall of the passivation layer.

7. The semiconductor structure according to claim 1, further comprising:
a dielectric layer located between the pad and the substrate.

8. The semiconductor structure according to claim 7, wherein the dielectric layer has a second recess, and the second recess is located directly below the first recess.

9. The semiconductor structure according to claim 8, wherein the pad fills the second recess.

10. The semiconductor structure according to claim 1, wherein a portion of the stress buffer layer filling the first recess forms a stress buffer ring.

11. The semiconductor structure according to claim 10, wherein a top-view pattern of the stress buffer ring is located within a contour of a top-view pattern of the pad.

12. The semiconductor structure according to claim 1, wherein a top-view pattern of the first recess comprises a ring shape.

13. The semiconductor structure according to claim 1, wherein a top-view pattern of the pad comprises a polygon or a circle.

14. The semiconductor structure according to claim 1, wherein the passivation layer comprises a single-layer structure.

15. The semiconductor structure according to claim 1, wherein the passivation layer comprises a multilayer structure.

16. The semiconductor structure according to claim 1, wherein a material of the stress buffer layer comprises a polymer material.

17. The semiconductor structure according to claim 16, wherein the polymer material comprises polyimide.

18. The semiconductor structure according to claim 1, wherein the bump is electrically connected to the pad.

19. The semiconductor structure according to claim 1, wherein the bump comprises a single-layer structure.

20. The semiconductor structure according to claim 1, wherein the bump comprises a multilayer structure.
